(19) United States
(12) Patent Application Publication
(10) Pub. No.: US 2013/0087179 A1
(43) Pub. Date: Apr. 11, 2013

(54) THERMOELECTRIC MODULE

(71) Applicants: Dong Hyeok Choi, Gyeonggi-do (KR); Yong Suk Kim, Gyeonggi-do (KR); Sung Ho Lee, Gyeonggi-do (KR)

(72) Inventors: Dong Hyeok Choi, Gyeonggi-do (KR); Yong Suk Kim, Gyeonggi-do (KR); Sung Ho Lee, Gyeonggi-do (KR)

(21) Appl. No.: 13/365,194

(22) Filed: Feb. 2, 2012

(30) Foreign Application Priority Data
Oct. 11, 2011 (KR) 10-2011-0103622

(51) Int. Cl. H01L 35/32

(52) U.S. Cl. 136/203; 136/224

(57) ABSTRACT

Provided is a thermoelectric module applied to an energy storage device cooling system to increase the cooling efficiency. The thermoelectric module includes P-type thermoelectric elements and N-type thermoelectric elements disposed alternately, a metal electrode provided between each P-type thermoelectric element and each N-type thermoelectric element, a heat absorbing plate connected to a bottom side of the metal electrode located between the P-type thermoelectric element and the N-type thermoelectric element, and a heat emitting plate connected to a top side of the metal electrode located between the N-type thermoelectric element and the P-type thermoelectric element.

### CROSS-REFERENCE TO RELATED APPLICATIONS

This application claims the benefit of Korean Patent Application No. 10-2011-0103622 filed with the Korea Intellectual Property Office on Oct. 11, 2011, the disclosure of which is incorporated herein by reference.

### BACKGROUND OF THE INVENTION

1. Field of the Invention

The present invention relates to a thermoelectric module, and more particularly, to a thermoelectric module having a structure capable of cooling each of the energy storage elements included in an energy storage device.

2. Description of the Related Art

A thermoelectric device uses the Seebeck effect that uses thermoelectric conversion to generate electromotive force by a temperature difference in the natural world or artifacts such as machines and buildings. In general, as disclosed in U.S. Patent Application Publication No. 2009-0025773, heat or carriers transfer in the perpendicular direction between the opposite surfaces of a cold region and a hot region in a thermoelectric material of a thermoelectric device.

The thermoelectric conversion is the conversion between thermal energy and electrical energy. The thermoelectric device has two applications: electricity generation using the Seebeck effect that generates electricity by the temperature difference between both ends of a thermoelectric material, and cooling (or refrigeration) using the Peltier effect that generates a temperature gradient between both ends of a thermoelectric material by flowing an electric current through the thermoelectric material.

The Seebeck effect can be used to convert heat, generated at computers or car engines, into electrical energy, and the Peltier effect can be used to implement various cooling systems without using coolants. Thus, an interest in thermoelectric devices has recently increased with an increase in the interest in new energy development, waste energy recovery, and environment protection.

Recently, an energy storage device used as an electric power source in the electric, electronic, communication, computer and automotive industries is fabricated in the shape of a module including a plurality of energy storage elements (e.g., lithium ion batteries or electrochemical capacitors) for the purpose of a high driving voltage. This, however, degrades the performance and life span of the energy storage device. Accordingly, extensive research is being conducted on an energy storage device cooling system using a thermoelectric module.

A description will now be given of the configuration and cooling operation of a conventional thermoelectric module, and the problems caused when the conventional thermoelectric module is applied to the above energy storage device.

FIG. 1 is a cutaway perspective view of a conventional thermoelectric module.

Referring to FIG. 1, a conventional thermoelectric module 1 includes P-type thermoelectric materials 3 and N-type thermoelectric materials 5. Electrodes 9 are attached in a predetermined pattern to a pair or dielectric substrates 7 formed of ceramic or silicon nitride, and the thermoelectric materials 3 and 5 are electrically connected in series by the electrodes 9.

In the conventional thermoelectric module 1, when a DC voltage is applied to the electrode 9 through a lead line 4 connected to a terminal 2, a side with a current flowing from the P-type thermoelectric material 3 to the N-type thermoelectric material 5 emits heat by the Peltier effect, and a side with a current flowing from the N-type thermoelectric material 5 to the P-type thermoelectric material 3 absorbs heat by the Peltier effect. Thus, the dielectric substrate 7 joined to the heat emitting side is heated, and the dielectric substrate 7 joined to the heat absorbing side is cooled.

An example of an energy storage device cooling system using the conventional thermoelectric module 1 is disclosed in Japanese Patent Application Publication No. 2005-057006. As disclosed in Japanese Patent Application Publication No. 2005-057006, a thermoelectric module (Reference numeral 14 of FIG. 3 of Japanese Patent Application Publication No. 2005-057006) is simply provided on an energy storage element (Reference numeral 10 of FIG. 3 of Japanese Patent Application Publication No. 2005-057006) to absorb or emit heat through a bottom dielectric substrate operating as a heat absorbing unit.

Alternatively, a thermoelectric module may be attached to the top or left/right side of an energy storage module.

However, energy storage elements are not independently cooled in the cooling system, thus degrading the cooling efficiency. That is, each energy storage element is a main heat-emitting component in an energy storage device, but a front or rear side occupying the largest area in the energy storage element is not cooled, thus degrading the cooling efficiency.

### PRIOR ART DOCUMENT

### Patent Document

Patent Document 1: Japanese Patent Application Publication No. 2005-057006

### SUMMARY OF THE INVENTION

The present invention has been invented in order to overcome the above-described problems and it is, therefore, an object of the present invention to provide a thermoelectric module having a structure capable of cooling each energy storage element to increase the cooling efficiency of an energy storage device.

In accordance with one aspect of the present invention to achieve the object, there is provided a thermoelectric module, which includes: P-type thermoelectric elements and N-type thermoelectric elements disposed alternately; a metal electrode provided between each P-type thermoelectric element and each N-type thermoelectric element; a heat absorbing plate connected to a bottom side of the metal electrode located between the P-type thermoelectric element and the N-type thermoelectric element; and a heat emitting plate connected to a top side of the metal electrode located between the N-type thermoelectric element and the P-type thermoelectric element.

In accordance with one aspect of the present invention to achieve the object, there is provided a thermoelectric module, which includes: N-type thermoelectric elements and P-type thermoelectric elements disposed alternately; a metal electrode provided between each N-type thermoelectric element and each P-type thermoelectric element; a heat absorbing plate connected to a bottom side of the metal electrode located between the N-type thermoelectric element and the P-type thermoelectric element; and a heat emitting plate connected to a top side of the metal electrode located between the P-type thermoelectric element and the N-type thermoelectric element.

The thermoelectric module may further include an energy storage element provided at one or both of the front and rear sides of the heat absorbing plate.

The P-type and/or N-type thermoelectric elements may be spaced apart from he heat absorbing plate by a predetermined distance.

The P-type and/or N-type thermoelectric elements may be spaced apart from the heat emitting plate by a predetermined distance.

The front side of the heat emitting plate may be exposed in the z-axis direction.

The front side of the heat absorbing plate and the front side of the metal electrode may be oriented at different angles.

The metal electrode, the heat absorbing plate, and the heat emitting plate may include at least one of cuprum (Cu), argentum (Ag), aurum (Au), aluminum (Al), and tungsten (W).

The heat absorbing plate may have a wider section than the energy storage element.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cutaway perspective view of a conventional thermoelectric module;

FIG. 2 is a front view of a thermoelectric module in accordance with an embodiment of the present invention;

FIG. 3 is a perspective view showing a portion of a thermoelectric module in accordance with an embodiment of the present invention;

FIG. 4 is a view showing the attachment of an energy storage element to a thermoelectric module in accordance with an embodiment of the present invention;

FIG. 5 is a view showing a heat transfer path in a thermoelectric module in accordance with an embodiment of the present invention; and

FIG. 6 is a front view of a thermoelectric module in accordance with another embodiment of the present invention.

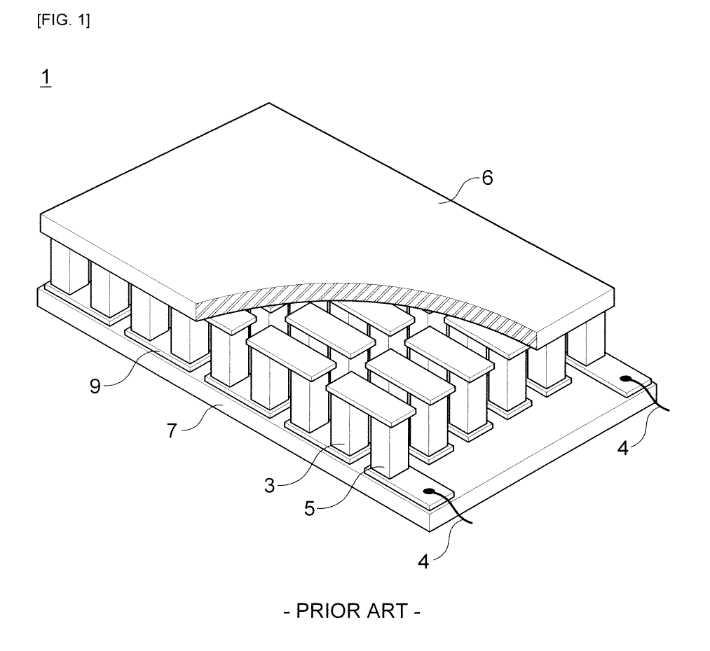

### DETAILED DESCRIPTION OF THE PREFERABLE EMBODIMENTS

Hereinafter, specific embodiments of the present invention will be described with reference to the accompanying drawings. However, the present invention is provided for the illustrative purpose only but not limited thereto.

The objects, features, and advantages of the present invention will be apparent from the following detailed description of embodiments of the invention with references to the accompanying drawings. The invention may be embodied in different forms and should not be construed as limited to the embodiments set forth herein. Rather, these embodiments are provided so that this disclosure will be thorough and complete, and will fully convey the scope of the invention to those skilled in the art. Like reference numerals denote like elements throughout the specification.

The terminology used herein is for the purpose of describing particular embodiments only and is not intended to limit the scope of the present invention. As used herein, the singular forms ‘a’, ‘an’ and ‘the’ are intended to include the plural forms as well, unless otherwise indicated. It will also be understood that the terms ‘comprise’, ‘include’ and ‘have’, when used in this specification, specify the presence of stated components, steps, operations, and/or elements, but do not preclude the presence or addition of one or more other components, steps, operations, and/or elements.

The configurations and operations of the present invention will be described below in detail with reference to the accompanying drawings.

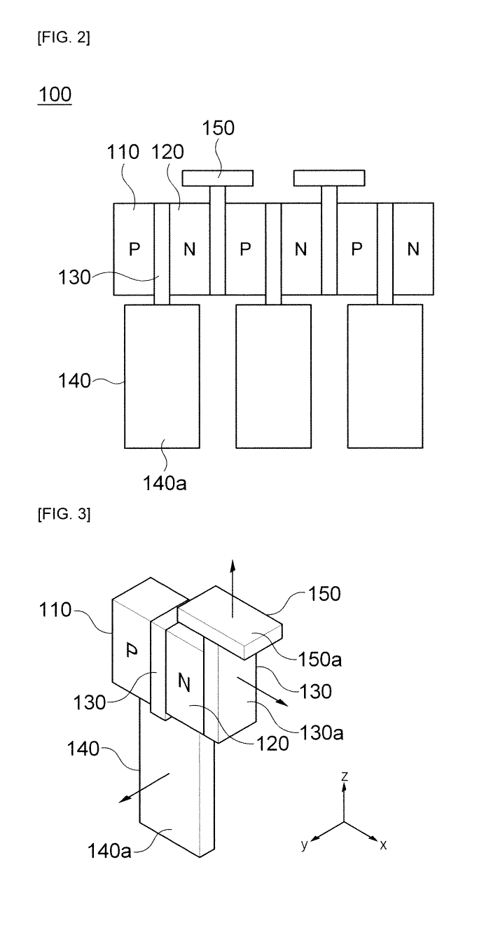

FIG. 2 is a front view of a thermoelectric module in accordance with an embodiment of the present invention. FIG. 3 is a perspective view showing a portion of the thermoelectric module in accordance with an embodiment of the present invention.

Referring to FIGS. 2 and 3, a thermoelectric module 100 in accordance with an embodiment of the present invention may include P-type thermoelectric elements 110 and N-type thermoelectric elements 120 disposed alternately, a metal electrode 130 provided between each P-type thermoelectric element 110 and each N-type thermoelectric element 120, a heat absorbing plate 140 connected to a bottom side of the metal electrode 130 located between the P-type thermoelectric element 110 and the N-type thermoelectric element 120, and a heat emitting plate 150 connected to a top side of the metal electrode 130 located between the N-type thermoelectric element 120 and the P-type thermoelectric element 110.

The P-type thermoelectric elements 110 and the N-type thermoelectric elements 120 may be any one used in the art, and may include at least two selected from the group consisting of bismuth (Bi), antimony (Sb), tellurium (Te), and selenium (Se).

The metal electrode 130 may be provided between each P-type thermoelectric element 110 and each N-type thermoelectric element 120 to electrically connect the P-type thermoelectric element 110 and the N-type thermoelectric element 120 in series.

In a conventional thermoelectric module, a P-type thermoelectric element and an N-type thermoelectric element are arranged alternately between a bottom electrode pattern and a top electrode pattern such that they are electrically connected in series and are structurally connected in parallel. However, in the thermoelectric module 100 in accordance with an embodiment of the present invention, the P-type thermoelectric elements 110 and N-type thermoelectric elements 120 are disposed alternately and the metal electrode 130 is provided between each P-type thermoelectric element 110 and each N-type thermoelectric element 120 such that they are connected in series not only electrically but also structurally.

The metal electrode 130 may include any material having high thermal conductivity. For example, the metal electrode 130 may include at least one of cuprum (Cu), argentum (Ag), aurum (Au), aluminum (Al), and tungsten (W).

Although not shown in the drawings, the thermoelectric module 100 may have metal electrodes at the left side of the leftmost P-type thermoelectric element among the P-type thermoelectric elements 110 and at the right side of the rightmost N-type thermoelectric element among the N-type thermoelectric elements 120 in order to apply a voltage to both ends thereof.

Accordingly, when a DC voltage is applied to the thermoelectric module 100, holes in the P-type thermoelectric element 110 may transfer to a negative (−) side and electrons in the N-type thermoelectric element 120 may transfer to a positive (+) side.

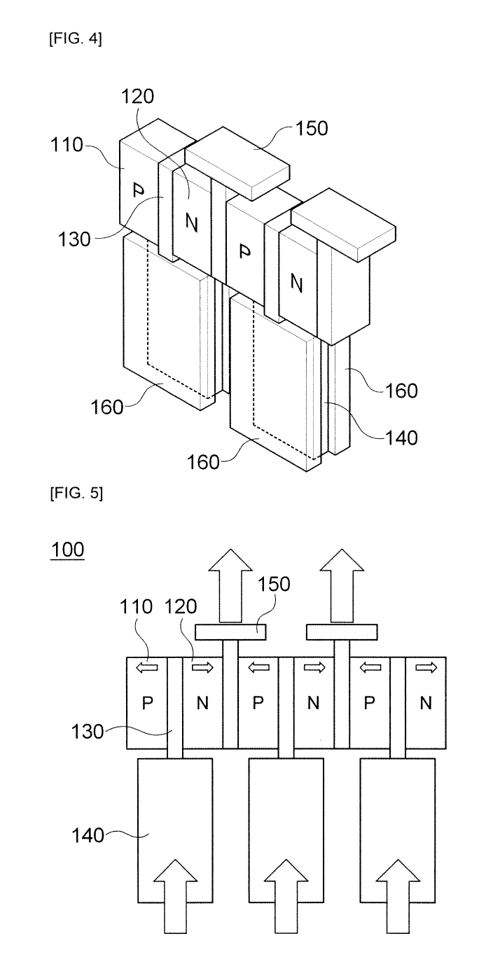

FIG. 4 is a view showing that an energy storage element is provided at the heat absorbing plate 140. Referring to FIG. 4, the heat absorbing plate 140 may absorb heat emitted by a cooling target. Accordingly, an energy storage element 160 may be located at a front side 140a (see FIG. 3) of the heat absorbing plate 140.

The energy storage element 160 may be any element storing energy. For example, the energy storage element 160 may be a lithium ion battery or an electrochemical capacitor.

The cooling target may be located at the front side 140a (see FIG. 3) of the heat absorbing plate 140, may be located at the rear side thereof, and may be located at both of the front and rear sides thereof.

In this manner, the widest side of the energy storage element emitting the most heat is located directly at the heat absorbing plate 140, and this structure is applied to each energy storage element to cool the energy storage element, thus making it possible to maximize the cooling efficiency, as compared to the conventional method of simply attaching a thermoelectric module to an energy storage device.

For more effective heat transfer, the heat absorbing plate 140 may be configured to have a wider section than the energy storage element 160. As a matter of course, it should be configured to prevent an electrical short between the heat absorbing plates 140.

The front side 140a (see FIG. 3) of the heat absorbing plate 140 and a front side 130a (see FIG. 3) of the metal electrode 130 may be oriented at different angles. As shown in FIG. 3, the front side 130a of the metal electrode 130 may be oriented in the x-axis direction, and the front side 140a of the heat absorbing plate 140 may be oriented in the y-axis direction.

Accordingly, the orientation angle of the heat absorbing plate can be changed suitably according to the orientation direction of the energy storage elements in the energy storage device. Accordingly, the thermoelectric module can be actively applied to various types of energy storage devices.

The P-type and/or N-type thermoelectric elements 110 and/or 120 may be spaced apart from the heat absorbing plate 140 by a predetermined distance.

If the P-type and/or N-type thermoelectric elements 110 and/or 120 directly contact the heat emitting plate 150, they may be physically damaged to degrade their thermoelectric performance, due to their low durability.

The heat emitting plate 150 may emit heat, absorbed by the heat absorbing plate 140, to the outside according to heat transfer. In particular, since a heat sink in may be disposed at a front side 150a (see FIG. 3) of the heat emitting plate 150, the front side 150a of the heat emitting plate 150 may be exposed in the z-axis direction as shown in FIG. 3.

Also, the P-type and/or N-type thermoelectric elements 110 and/or 120 may be spaced apart from the heat emitting plate 150 by a predetermined distance.

The heat absorbing plate 140 and the heat emitting plate 150 may include any material having high thermal conductivity. For example, the heat absorbing plate 140 and the heat emitting plate 150 may include at least one of cuprum (Cu), argentum (Ag), aurum (Au), aluminum (Al), and tungsten (W).

FIG. 5 is a view showing a heat transfer path in the thermoelectric module in accordance with an embodiment of the present invention. A detailed description will now be given of a cooling method according to a heat transfer path in the thermoelectric module 100 in accordance with an embodiment of the present invention.

Although not shown in the drawings, the thermoelectric module 100 may have metal electrodes at the left side of the leftmost P-type thermoelectric element among the P-type thermoelectric elements 110 and at the right side of the rightmost N-type thermoelectric element among the N-type thermoelectric elements 120 in order to apply a voltage to both ends thereof.

In this structure, when a negative (−) voltage is applied to the leftmost P-type thermoelectric element among the P-type thermoelectric elements 110 and a positive (+) voltage is applied to the rightmost N-type thermoelectric element among the N-type thermoelectric elements 120, holes in each P-type thermoelectric element 110 transfer to the right side of the metal electrode 130 with the heat absorbed by the heat absorbing plate 140, and electrons in each N-type thermoelectric element 120 transfer to the left side of the metal electrode 130 with the heat absorbed by the heat absorbing plate 140.

The heat transferred by each P-type thermoelectric element 110 and each N-type thermoelectric element 120 are concentrated on the metal electrode 130, and the heat concentrated on the metal electrode 130 is emitted through the heat emitting plate 150 to perform a cooling operation.

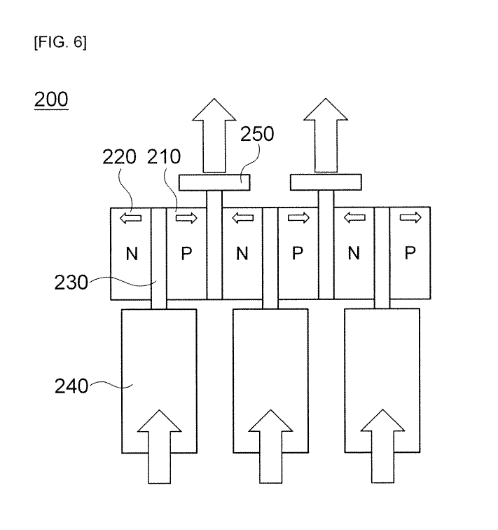

FIG. 6 is a front view of a thermoelectric module in accordance with another embodiment of the present invention. Referring to FIG. 6, a thermoelectric module 200 in accordance with another embodiment of the present invention may include N-type thermoelectric elements 220 and P-type thermoelectric elements 210 disposed alternately, a metal electrode 230 provided between each N-type thermoelectric element 220 and each P-type thermoelectric element 210, a heat absorbing plate 240 connected to a bottom side of the metal electrode 230 located between the N-type thermoelectric element 220 and the P-type thermoelectric element 210, and a heat emitting plate 250 connected to a top side of the metal electrode 230 located between the P-type thermoelectric element 210 and the N-type thermoelectric element 220.

Although not shown in the drawings, the thermoelectric module 200 may have metal electrodes at the left side of the leftmost N-type thermoelectric element among the N-type thermoelectric elements 220 and at the right side of the rightmost P-type thermoelectric element among the P-type thermoelectric elements 210 in order to apply a voltage to both ends thereof.

In this structure, when a positive (+) voltage is applied to the leftmost N-type thermoelectric element among the N-type thermoelectric elements 220 and a negative (−) voltage is applied to the rightmost P-type thermoelectric element among the P-type thermoelectric elements 210, holes in each P-type thermoelectric element 210 transfer to the left side of the metal electrode 230 with the heat absorbed by the heat absorbing plate 240, and electrons in each N-type thermoelectric element 220 transfer to the right side of the metal electrode 230 with the heat absorbed by the heat absorbing plate 240.

The heat transferred by each P-type thermoelectric element 210 and each N-type thermoelectric element 220 are concentrated on the metal electrode 230, and the heat concentrated on the metal electrode 230 is emitted through the heat emitting plate 250 to perform a cooling operation.

Unlike the thermoelectric module 100 of FIG. 2, according to this heat transfer path, the thermoelectric module 200 may have the heat absorbing plate 240 connected to the bottom side of the metal electrode 230 located between the N-type thermoelectric element 220 and the P-type thermoelectric element 210, and may have the heat emitting plate 250 connected to the top side of the metal electrode 230 located between the P-type thermoelectric element 210 and the N-type thermoelectric element 220.

Like the thermoelectric module 100 of FIG. 2, the thermoelectric module 200 may further include an energy storage element provided at one or both of the front and rear sides of the heat absorbing plate 240.

The P-type and/or N-type thermoelectric elements 210 and/or 220 may be spaced apart from the heat absorbing plate 240 by a predetermined distance. Also, the P-type and/or N-type thermoelectric elements 210 and/or 220 may be spaced apart from the heat emitting plate 250 by a predetermined distance.

Since the thermoelectric module 200 may have a heat sink pin disposed at the heat emitting plate 250, the front side of the heat emitting plate 250 may be exposed in the z-axis direction.

The front side of the heat absorbing plate 240 and the front side of the metal electrode 230 may be oriented at different angles.

The metal electrode 230, the heat absorbing plate 240, and the heat emitting plate 250 may include any material having high thermal conductivity. For example, the metal electrode 230, the heat absorbing plate 240, and the heat emitting plate 250 may include at least one of cuprum (Cu), argentum (Ag), aurum (Au), aluminum (Al), and tungsten (W). The heat absorbing plate 240 may be configured to have a wider section than the energy storage element to increase the cooling efficiency.

As described above, when a thermoelectric module in accordance with the present invention is applied to an energy storage device cooling system, energy storage elements included in the energy storage device can be independently cooled, thus maximizing the cooling efficiency.

Although the preferable embodiments of the present invention have been shown and described above, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A thermoelectric module, which comprises:
P-type thermoelectric elements and N-type thermoelectric elements disposed alternately;
a metal electrode provided between each P-type thermoelectric element and each N-type thermoelectric element;
a heat absorbing plate connected to a bottom side of the metal electrode located between the P-type thermoelectric element and the N-type thermoelectric element; and
a heat emitting plate connected to a top side of the metal electrode located between the N-type thermoelectric element and the P-type thermoelectric element.

2. A thermoelectric module, which comprises:
N-type thermoelectric elements and P-type thermoelectric elements disposed alternately;
a metal electrode provided between each N-type thermoelectric element and each P-type thermoelectric element;
a heat absorbing plate connected to a bottom side of the metal electrode located between the N-type thermoelectric element and the P-type thermoelectric element; and
a heat emitting plate connected to a top side of the metal electrode located between the P-type thermoelectric element and the N-type thermoelectric element.

3. The thermoelectric module according to claim 1 or 2, which further comprises an energy storage element provided at one or both of the front and rear sides of the heat absorbing plate.

4. The thermoelectric module according to claim 1 or 2, wherein the P-type and/or N-type thermoelectric elements are spaced apart from the heat absorbing plate by a predetermined distance.

5. The thermoelectric module according to claim 1 or 2, wherein the P-type and/or N-type thermoelectric elements are spaced apart from the heat emitting plate by a predetermined distance.

6. The thermoelectric module according to claim 1 or 2, wherein the front side of the heat emitting plate is exposed in the z-axis direction.

7. The thermoelectric module according to claim 1 or 2, wherein the front side of the heat absorbing plate and the front side of the metal electrode are oriented at different angles.

8. The thermoelectric module according to claim 1 or 2, wherein the metal electrode, the heat absorbing plate, and the heat emitting plate comprise at least one of cuprum (Cu), argentum (Ag), aurum (Au), aluminum (Al), and tungsten (W).

9. The thermoelectric module according to claim 3, wherein the heat absorbing plate has a wider section than the energy storage element.
